(19) United States
(12) Patent Application Publication
(10) Pub. No.: US 2025/0072148 A1
(43) Pub. Date: Feb. 27, 2025

(54) DEEP TRENCH ISOLATION STRUCTURE FOR IMAGE SENSOR

(71) Applicant: Taiwan Semiconductor Manufacturing Company, Ltd., Hsinchu (TW)

(72) Inventors: Yen-Ting Chiang, Tainan City (TW); Yen-Yu Chen, Kaohsiung City (TW); Tzu-Jui Wang, Fengshan City (TW); Jen-Cheng Liu, Hsin-Chu City (TW); Dun-Nian Yaung, Taipei City (TW)

(21) Appl. No.: 18/454,107

(22) Filed: Aug. 23, 2023

(51) Int. Cl. H01L 27/146

(52) U.S. Cl. CPC H01L 27/1463; H01L 27/14683

(57) ABSTRACT

In some embodiments, the present disclosure relates to an image sensor including a substrate having a first side and a second side opposite the first side; a photodetector region within the substrate; a gate structure on the first side of the substrate over the photodetector region; a deep trench isolation (DTI) structure surrounding the photodetector region and extending from the first side of the substrate to the second side; a doped floating node region within the substrate at the first side and disposed between the gate structure and the DTI structure; and a floating node on the first side of the substrate, contacting a top surface of the DTI structure and overlying the doped floating node region.

### BACKGROUND

Many modern day electronic devices include image sensors. Image sensors have a photodetector, and transfer gate, and a floating node. The transfer gate is configured to form a conductive path between the photodetector and the floating node, resulting in a charge in the photodetector being transferred through the floating node to image processing circuitry. The photodetectors are often spaced from one another by a deep trench isolation structure.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a cross-sectional view of some embodiments of an image sensor having a DTI structure extending through the substrate.

FIGS. 2A-2B illustrate a cross-sectional view and a top down view of some embodiments of an image sensor having a DTI structure extending through the substrate and a shared floating node overlying the DTI structure.

FIGS. 3A-3E illustrate cross-sectional views of some embodiments of an image sensor having a DTI structure extending through the substrate in various configurations.

FIGS. 4-19 illustrate cross-sectional views of some embodiments of a method of forming an image sensor having a DTI structure extending through the substrate with a backside DTI structure with a same width as a frontside DTI structure.

FIGS. 20-34 illustrate cross-sectional views of some embodiments of a method of forming an image sensor having a DTI structure extending through the substrate with the backside DTI structure having with a lower width than the frontside DTI structure.

FIG. 35 illustrates a flow diagram of some embodiments of a method of forming an integrated chip having an image sensor having a DTI structure extending through the substrate.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Image sensors may comprise a plurality of photodetectors in a substrate. The photodetectors are arranged in a grid pattern within openings of a deep trench isolation (DTI) structure. The transfer gates overlie the photodetectors on a first side of the substrate. Operation of the transfer gates results in charge from the photodetectors being transferred to floating nodes, where the charge is then transferred to an image processing circuit.

In some image sensors, the floating nodes may be individual to the photodetectors, such that the photodetectors and the floating nodes are grouped together within active regions of the substrate that are laterally surrounded by the DTI structure. Such an arrangement increases the minimum layout requirements of the image sensor in order to fit the floating nodes and photodetectors within the grid pattern. Individual floating nodes may also increase the capacitance of the floating node due to the increased number of contacts and lower the conversion gain of the image sensor, resulting in a lower amount of charge being transferred for a specified applied voltage.

Floating nodes may also be shared between multiple photodetectors, when the floating nodes are positioned at a midpoint between the photodetectors. Such an arrangement reduces the isolation of the photodetectors, as “fingers” of the DTI structure do not fully surround the photodetectors in order to make space for the floating node. This lack of isolation results in worse optical performance for the photodetectors due to the greater interference between cells of the image sensor. Therefore, an image sensor that has the isolation of the individual floating node design while having the relaxed layout requirements of a shared floating node design is desirable.

The present disclosure provides an image sensor having a DTI structure extending through the substrate and a shared floating node overlying the DTI structure. The DTI structure is formed by fabricating a frontside DTI structure with a seal layer extending partially into the substrate. The floating node is formed over the frontside DTI structure, extending over sidewalls of the frontside DTI structure to couple to the cells of the image sensor. After the frontside DTI structure and other frontside processes are completed, a backside DTI structure is formed beneath the frontside DTI structure. The backside DTI structure is formed using a self-aligned etch, resulting in a DTI structure that extends through the substrate. The above process results in a DTI structure that extends from a lower surface of the floating node to a second surface of the substrate, increasing the isolation of the photodetectors while maintaining a shared floating node.

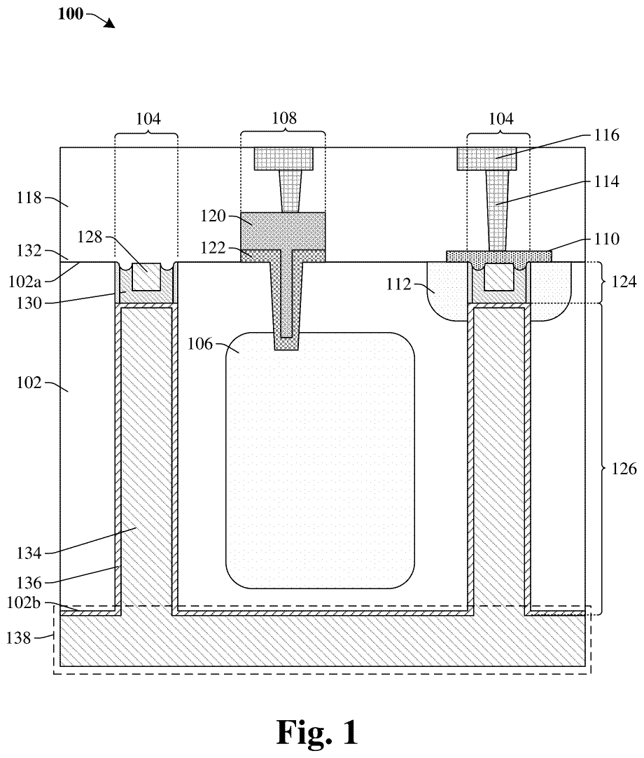

FIG. 1 illustrates a cross-sectional view 100 of some embodiments of an image sensor having a DTI structure extending through the substrate.

A DTI structure 104 comprising a frontside DTI structure 124 and a backside DTI structure 126 is disposed within a substrate 102. The DTI structure 104 surrounds a photodetector 106 within the substrate 102. A transfer gate 108 is on a first side 102a of the substrate and overlies the photodetector 106. In some embodiments, the transfer gate 108 extends into the substrate 102 towards the photodetector 106. A floating node 110 overlies the DTI structure 104 on the first side 102a of the substrate 102. The floating node 110 conforms to an upper surface of the DTI structure 104, and is surrounded by a floating node region 112. The floating node region 112 is a doped region of a first doping type and the photodetector 106 is a doped region of the first doping type. In some embodiments, the transfer gate 108 is spaced from the floating node region 112 to reduce the amount of gate-induced drain leakage. An interconnect structure 116 is coupled to the transfer gate 108 and the floating node 110 by contacts 114.

The frontside DTI structure 124 comprises a first insulative core 128 surrounded by a seal layer 130 and an insulative layer 132. In some embodiments, the first insulative core 128 is or comprises an oxide (e.g., silicon dioxide (SiO₂)) or the like. In some embodiments, the insulative layer 132 is or comprises an oxide (e.g., silicon dioxide (SiO₂)) or the like. The seal layer 130 extends beneath the first insulative core 128, separating the first insulative core 128 from the backside DTI structure 126. The seal layer 130 has a “U” shaped cross-section. The insulative layer 132 surrounds outers sidewalls of the seal layer 130 and extends over a first side 102a of the substrate 102. In some embodiments, the portion of the insulative layer 132 extending over the first side 102a of the substrate is separated from the portion of the insulative layer 132 that surrounds outer sidewalls of the seal layer 130.

The backside DTI structure 126 comprises a second insulative core 134 surrounded by a high-k layer 136. The high-k layer 136 extends over the second insulative core 134, separating the second insulative core from the frontside DTI structure 124. The high-k layer 136 extends across a second side 102b of the substrate 102. The second insulative core 134 extends out of an insulative base portion 138. The insulative base portion 138 is separated from the substrate 102 by the high-k layer 136. The insulative base portion protects the high-k layer 136 from damage. The use of the backside DTI structure 126 that extends from the frontside DTI structure 124 to the second side 102b of the substrate in combination with the frontside DTI structure 124 that extends from the floating node 110 to the backside DTI structure results in an image sensor with greater isolation that may still utilize a shared floating node.

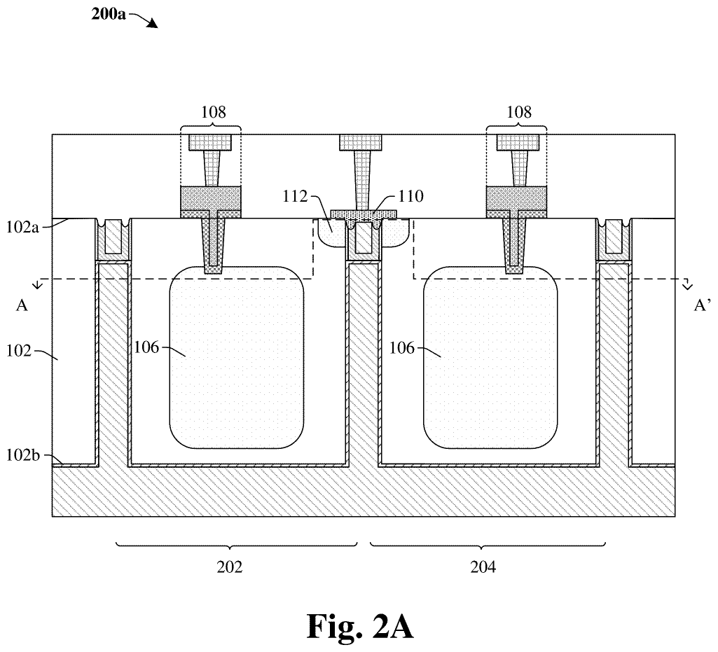

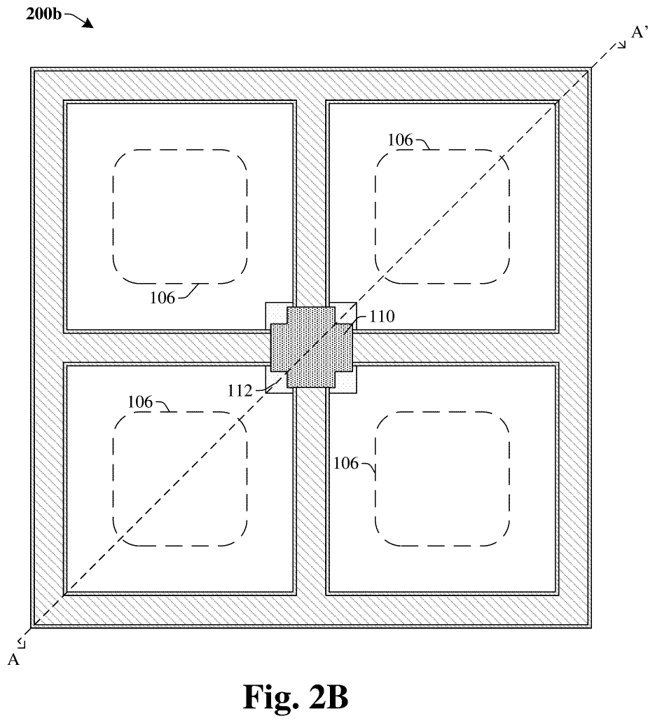

FIGS. 2A-2B illustrate a cross-sectional view 200a and a top view 200b of some embodiments of an image sensor having a DTI structure extending through the substrate and a shared floating node overlying the DTI structure. The cross-sectional view 200a of FIG. 2A may, for example, be taken along line A-A′ in FIG. 2B.

The floating node 110 is electrically coupled to a floating node region 112 that extends into a first cell 202 and a second cell 204 in the image sensor. The floating node region 112 is configured to conduct the charge from one of the photodetectors 106 into the floating node 110 when the corresponding transfer gate 108 is biased. The DTI structure 104 extending from the floating node 110 to the second side 102b of the substrate 102 increases the isolation between the photodetectors, increasing the optical performance of the image sensor. Further, using one floating node 110 for multiple photodetectors 106 reduces the total number of contacts on the image sensor, reducing the capacitance of the floating node 110 and increasing the conversion gain (e.g., the amount of charge transferred with a specified voltage applied) compared to related image sensors.

As shown in the top view 200b of FIG. 2B, four photodetectors 106 may be positioned around one floating node 110. The floating node region 112 extends into four separate cells of the image sensor, such that the four photodetectors 106 may transfer their charge through the floating node 110 during one read out operation. The DTI structure 104 further extends all the way to the floating node 110, completing the isolation of the photodetectors 106 from one another.

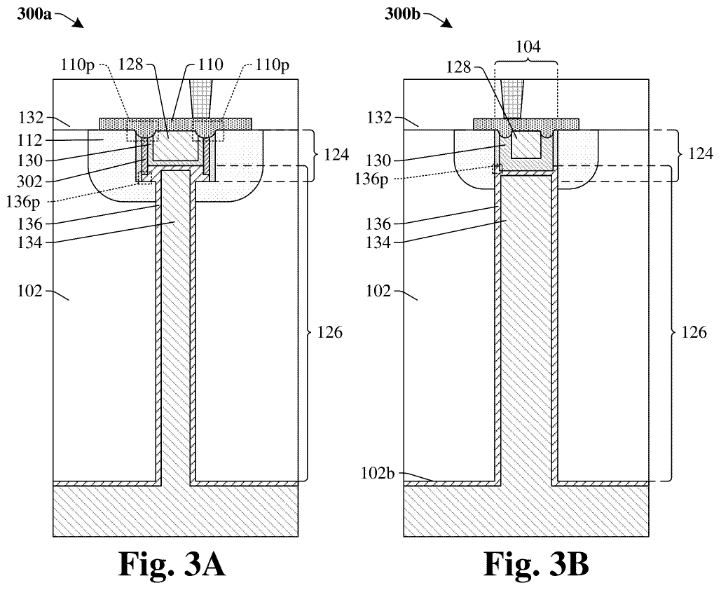

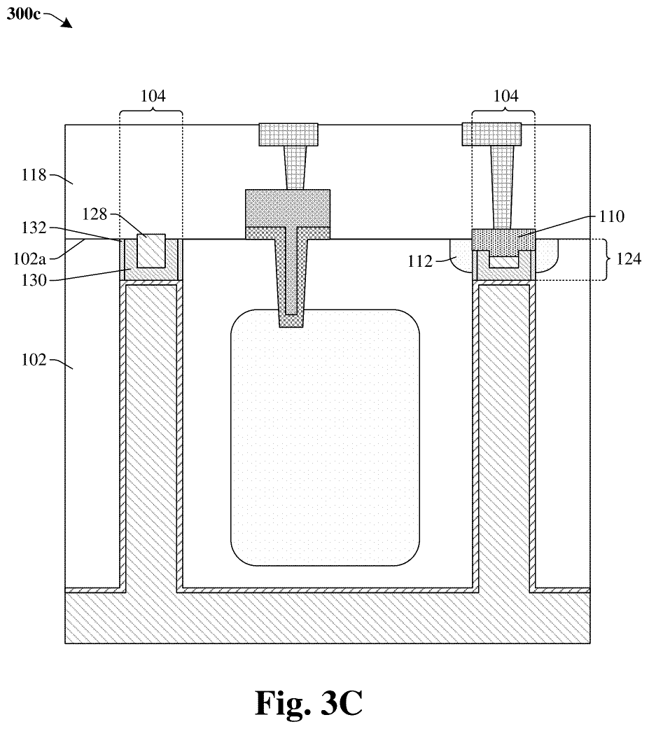

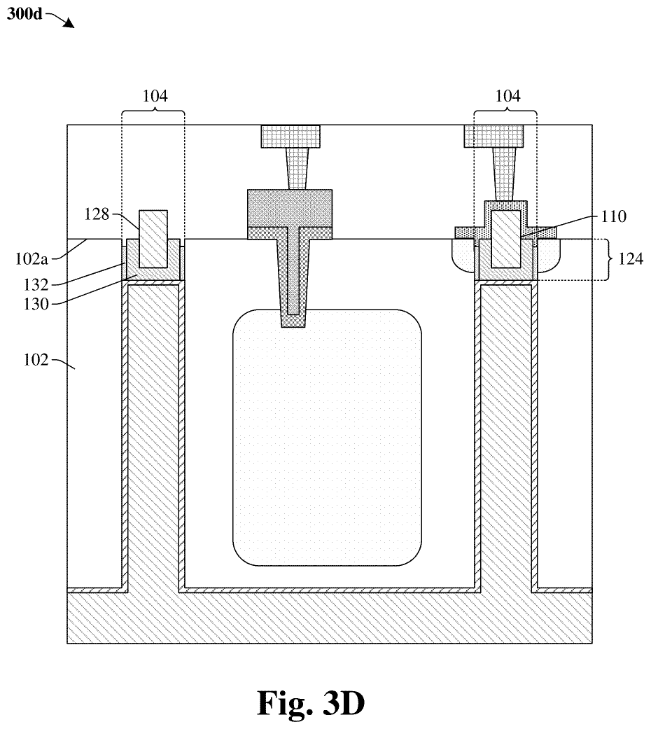

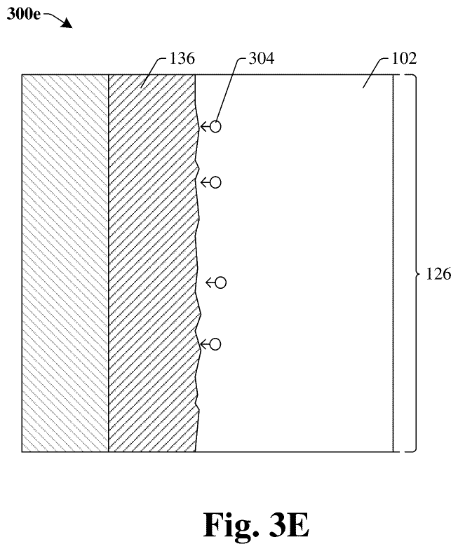

FIGS. 3A-3E illustrate cross-sectional views 300a-300e of some embodiments of an image sensor having a DTI structure extending through the substrate in various configurations.

As shown in the cross-sectional view 300a of FIG. 3A, in some embodiments, the backside DTI structure 126 extends over a bottom surface of the frontside DTI structure 124. In some embodiments, the portion of the backside DTI structure 126 at an elevation level with the frontside DTI structure 124 has a greater width than the portion of the backside DTI structure 126 below the bottom surface of the frontside DTI structure 124. In some embodiments, the frontside DTI structure 124 has a greater width than the backside DTI structure 126. In further embodiments, the first insulative core 128 may have a greater width than the second insulative core 134. In some embodiments, the frontside DTI structure 124 further comprises a second insulative layer 302 surrounding the seal layer 130 and spacing the seal layer 130 from the insulative layer 132. In some embodiments, the second insulative layer 302 is or comprises a nitride (e.g., silicon nitride (Si₃N₄)) or the like. In some embodiments, the floating node region 112 extends beneath a bottom surface of the frontside DTI structure 124. In some embodiments, the high-k layer 136 extends around a sidewall and a bottom surface of the second insulative layer 302, and has a protrusion 136p extends towards and contacting the insulative layer 132.

The frontside DTI structure 124 has indentations over the seal layer 130, second insulative layer 302, and insulative layer 132. The indentations extend in a square pattern around sidewalls of the frontside DTI structure 124. The insulative core 128 has a flat upper surface that extends between the indentations. The floating node 110 has protrusions 110p that extend into the frontside DTI structure 124, filling the indentations. In some embodiments, the floating node 110 contacts the substrate 102. In other embodiments, a thin portion of the insulative layer 132 extends between the floating node 110 and the substrate 102. In some embodiments, a top surface of the backside DTI structure 126 extends to a first height measured from the second side 102b of the substrate 102, and a bottom surface of the frontside DTI structure 124 extends to a second height measured from the second side 102b of the substrate 102, where the second height is greater than the first height.

As shown in the cross-sectional view 300b of FIG. 3B, in some embodiments, the frontside DTI structure 124 has an equal width to the backside DTI structure 126. In further embodiments, the second insulative core 134 may have a greater width than the second insulative core 134. In some embodiments, the high-k layer 136 has protrusions 136p that extend up outer sidewalls of the seal layer 130. The protrusions extend away from the second side 102b of the substrate 102 and have uppermost surfaces contacting the insulative layer 132. In some embodiments, the DTI structure 104 is tapered, having a greater width near the first side 102a of the substrate 102 and a lower width near the second side 102b of the substrate 102.

As shown in the cross-sectional view 300c of FIG. 3C, in some embodiments, portions of the seal layer 130 directly beneath the floating node 110 may extend to a different depth within the substrate 102 than portions of the seal layer 130 and first insulative core 128 spaced from the floating node 110. In some embodiments, upper surfaces of the seal layer 130 and the insulative layer 132 that are spaced from the floating node 110 may be substantially level with the first side 102a of the substrate 102. In further embodiments portions of the first insulative core 128 spaced from the floating node 110 may extend over the first side 102a of the substrate 102. Further, portions of the first insulative core 128 and seal layer 130 directly beneath the floating node 110 are depressed into the first side 102a of the substrate 102. In some embodiments, the floating node 110 has a protrusion extending from a lower side of the floating node 110 that covers an upper surface of the first insulative core 128. That is, the upper surface of the first insulative core is beneath an upper surface of the seal layer 130.

As shown in the cross-sectional view 300d of FIG. 3D, in some embodiments, the insulative layer 132 may be recessed from the first side of the substrate 102 while the first insulative core 128 may extend over the substrate 102. In further embodiments, the floating node 110 may extend into the substrate 102 to contact the insulative layer 132 and extend over the first insulative core 128 to extend past opposite sides of the frontside DTI structure 124.

As shown in the cross-sectional view 300c of FIG. 3E, the interface between the substrate 102 and the high-k layer 136 may be textured. During the process of forming the backside DTI structure 126, multiple etching processes are performed on the substrate 102, including a dry plasma etch and a wet etch. The etching processes may damage the substrate 102, introducing charge traps and stray charge carriers 304 near the surface of the substrate 102. The charge traps and stray charge carriers 304 at the interface with the backside DTI structure 126 may increase the dark current in the image sensor. In some embodiments, implantation processes used to form the floating node regions (see 112 of FIG. 1) and the photodetector (see 106 of FIG. 1) may also damage the substrate 102 and introduce stray charge carriers 304. The formation of the high-k layer 136 after the etching processes and implantation processes may reduce the number of charge traps at the interfaces and attract charge carriers 304 from the substrate 102, reducing the amount of dark current detected from the image sensor. In some embodiments, boron is incorporated into the high-k layer 136 at the substrate 102 to high-k layer 136 interface to reduce the amount of dark current. In some embodiments, the high-k layer 136 is charged to accumulate charge carriers from the substrate 102. It will be appreciated that the features shown in FIGS. 3C-3E may be applicable to the other embodiments described herein.

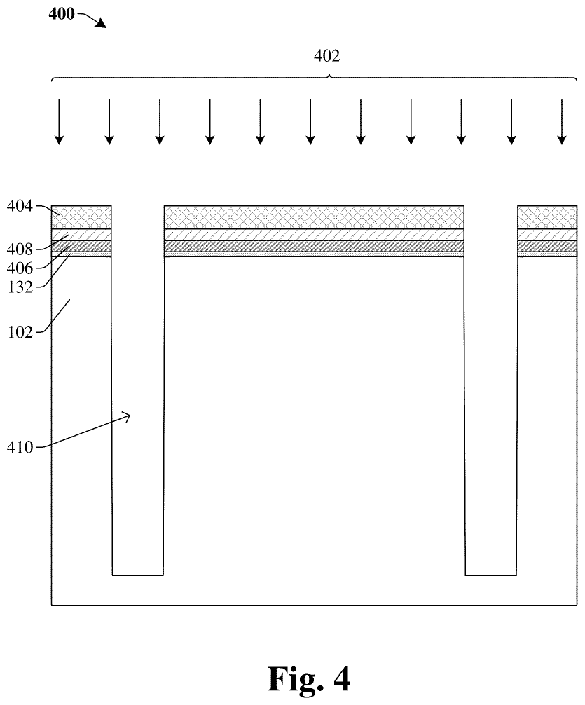

FIGS. 4-19 illustrate cross-sectional views of some embodiments of a method of forming an image sensor having a DTI structure extending through the substrate with a backside DTI structure with a same width as a frontside DTI structure. Although FIGS. 4-19 are described in relation to a method, it will be appreciated that the structures disclosed in FIGS. 4-19 are not limited to such a method, but instead may stand alone as structures independent of the method.

As shown in cross-sectional view 400 of FIG. 4, the substrate 102 is provided. An insulative layer 132 is formed on the substrate 102. In some embodiments, the insulative layer 132 is a thermal oxide. A first nitride layer 406 is formed over the insulative layer 132. A first hard mask layer 408 is formed over the first nitride layer 406. A first masking layer 404 is formed over the first nitride layer 406. In some embodiments, the first nitride layer 406 and the first hard mask layer 408 are formed using one of chemical vapor deposition (CVD), physical vapor deposition (PVD), atomic layer deposition (ALD), some other suitable deposition process, or a combination of the foregoing. In some embodiments, the first masking layer 404 is a photoresist. In some embodiments, the first nitride layer 406 is or comprises silicon nitride (Si₃N₄) or the like. In some embodiments, the first hard mask layer 408 is or comprises silicon oxide (SiO₂), densified silicon dioxide, or the like.

After the formation of the first masking layer 404, the first masking layer 404 is then patterned to form openings. In some embodiments, the first masking layer 404 is patterned using photolithography. A first etching process 402 is then performed. During the first etching process 402, the first hard mask layer 408, the first nitride layer 406, the insulative layer 132, and the substrate 102 are etched in the regions that are exposed by the first masking layer 404. In some embodiments, first etching process 402 may be a dry etch such as a plasma etch or the like. The first etching process 402 results in first trenches 410 formed in the substrate 102 in a pattern corresponding to the openings in the first masking layer 404. The pattern is a grid pattern. The first masking layer 404 is subsequently removed.

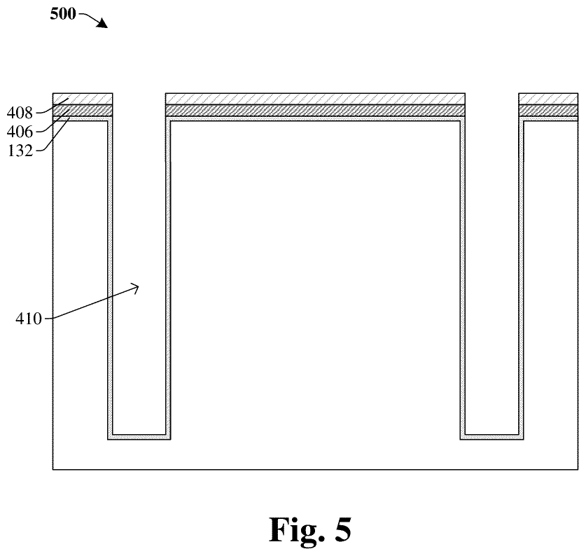

As shown in cross-sectional view 500 of FIG. 5, a lining oxide is formed across the surface of the first trench 410, extending the insulative layer 132 along surfaces of the trench. In some embodiments, the lining oxide is formed using a thermal process, a deposition process, or a combination of the foregoing.

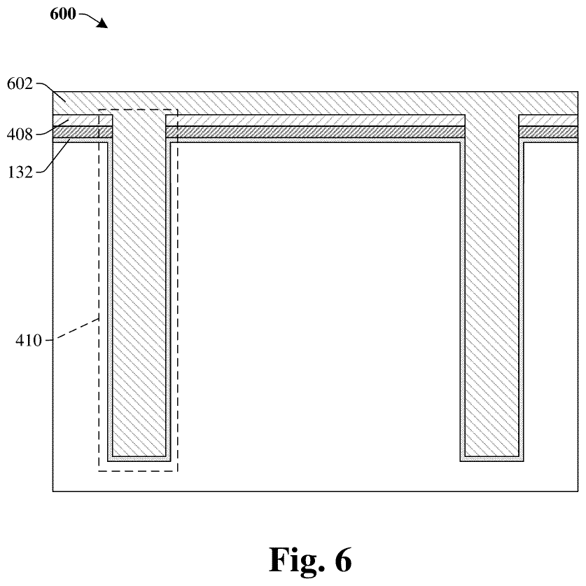

As shown in the cross-sectional view 600 of FIG. 6, a first conformal oxide layer 602 is deposited in the first trench 410 (shown in phantom). The first conformal oxide layer 602 fills the first trench 410 and overlies the first hard mask layer 408. In some embodiments, the first conformal oxide layer 602 may be deposited using one of CVD, PVD, ALD, some other suitable deposition process, or a combination of the foregoing.

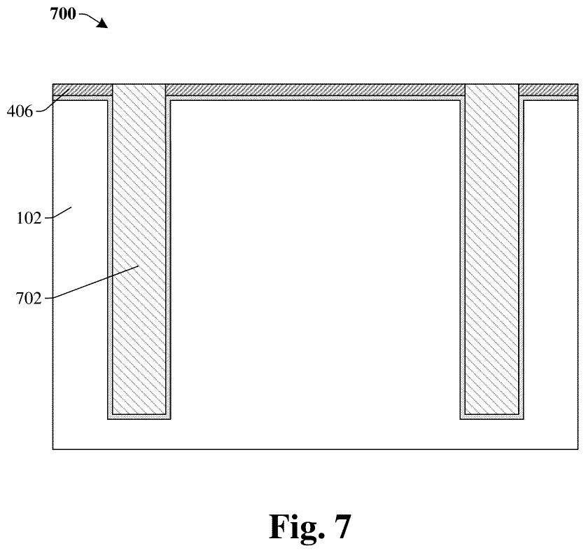

As shown in cross-sectional view 700 of FIG. 7, the first hard mask layer (see 408 of FIG. 6) and a portion of the first conformal oxide layer (see 602 of FIG. 6) extending over a top surface of the first nitride layer 406 are removed. In some embodiments, the portion of the first conformal oxide layer (sec 602 of FIG. 6) and the first hard mask layer (see 408 of FIG. 6) are removed using a planarization process (e.g., a chemical mechanical planarization process). The removal process results in a first sacrificial core 702 remaining in the substrate 102.

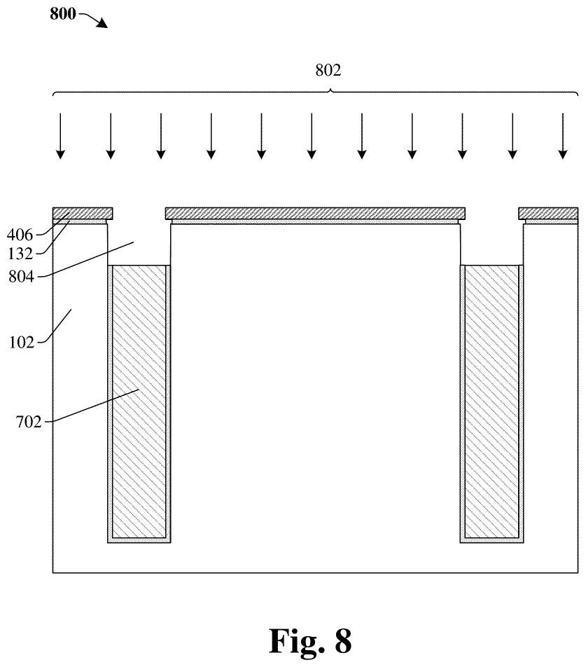

As shown in cross-sectional view 800 of FIG. 8, a portion of the first sacrificial core 702 and a portion of the insulative layer 132 are removed during a second etching process 802. leaving first openings 804. In some embodiments, the etching process is a wet etching process configured to etch silicon dioxide (SiO₂).

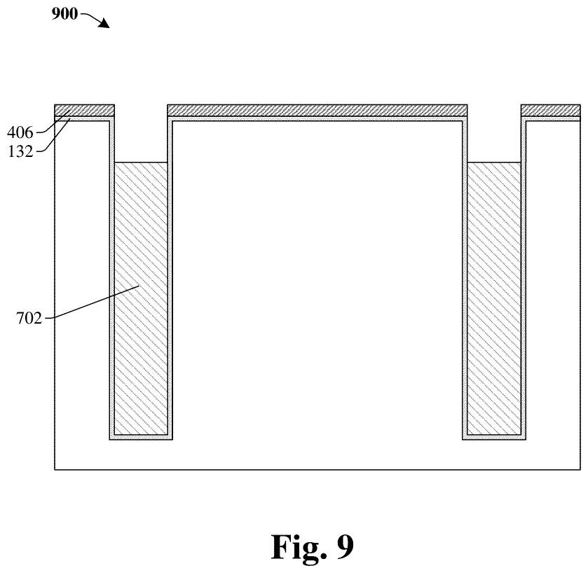

As shown in cross-sectional view 900 of FIG. 9, a second lining oxide is formed over the exposed sidewalls of the substrate 102, and an anneal is performed, reforming the oxide layer between the first nitride layer 406 and the first sacrificial core 702.

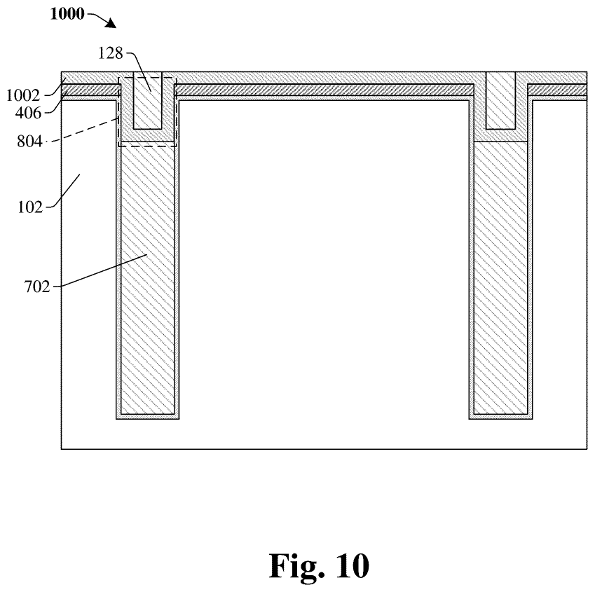

As shown in the cross-sectional view 1000 of FIG. 10, a conformal seal layer 1002 is formed over the first nitride layer 406. In some embodiments, the conformal seal layer 1002 is or comprises densified silicon dioxide (SiO₂), silicon nitride, polysilicon, a silicon epitaxial layer, a combination of the foregoing, or the like. The conformal seal layer 1002 conforms to the first openings 804 and the first nitride layer 406. After the conformal seal layer 1002 is formed, a first insulative core 128 is formed over the conformal seal layer 1002. The first insulative core 128 is formed by depositing a conformal oxide layer over the substrate 102, then removing portions of the conformal oxide layer over an upper surface of the conformal seal layer 1002 using a planarization process (e.g., a CMP process). In some embodiments, the first insulative core is or comprises silicon dioxide (SiO₂) or the like.

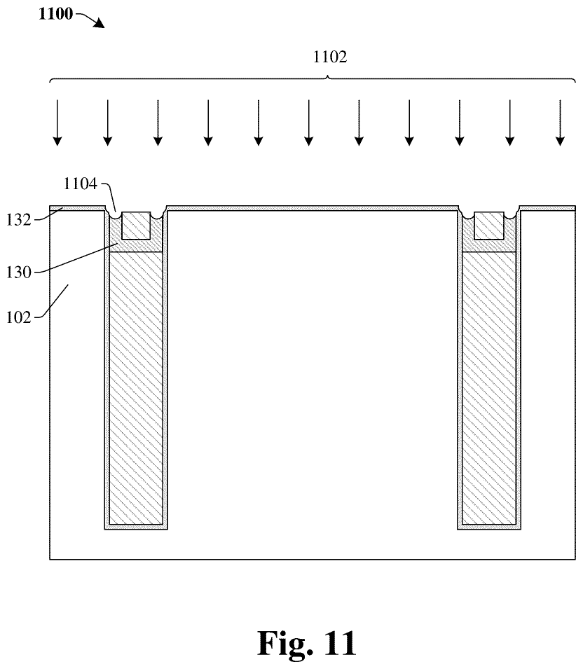

As shown in cross-sectional view 1100 of FIG. 11, portions of the conformal seal layer (see 1002 of FIG. 10) over the first side 102a of the substrate 102 are removed, and the first nitride layer (see 406 of FIG. 10) is removed, such that the seal layer 130 remains within the substrate 102. In some embodiments, the portions of the conformal seal layer (see 1002 of FIG. 10) and the first nitride layer (see 406 of FIG. 10) are removed using one or more wet etching processes 1102. That is, in some embodiments, the portions of the conformal seal layer (see 1002 of FIG. 10) may be removed using a first wet etching process selective for the material of the seal layer 130, and the first nitride layer (see 406 of FIG. 10) may subsequently be removed using a second wet etching process with an etch chemistry selective to silicon nitride. In some embodiments, where the seal layer 130 comprises a nitride (e.g., silicon nitride (Si₃N₄)), the portions of the conformal seal layer (see 1002 of FIG. 10) and the first nitride layer (see 406 of FIG. 10) may be removed using a single wet etching process 1102. The one or more wet etching processes 1102 result in indentations 1104 being formed within the seal layer 130. The indentations extend in square patterns around the openings in the grid pattern of the seal layer 130. In some embodiments, the wet etching processes 1102 used to remove the portions of the conformal seal layer (see 1002 of FIG. 10) and the first nitride layer (see 406 of FIG. 10) also remove portions of the insulative layer 132. In some embodiments, the one or more wet etching processes 1102 expose portions of the substrate 102 near the seal layer 130.

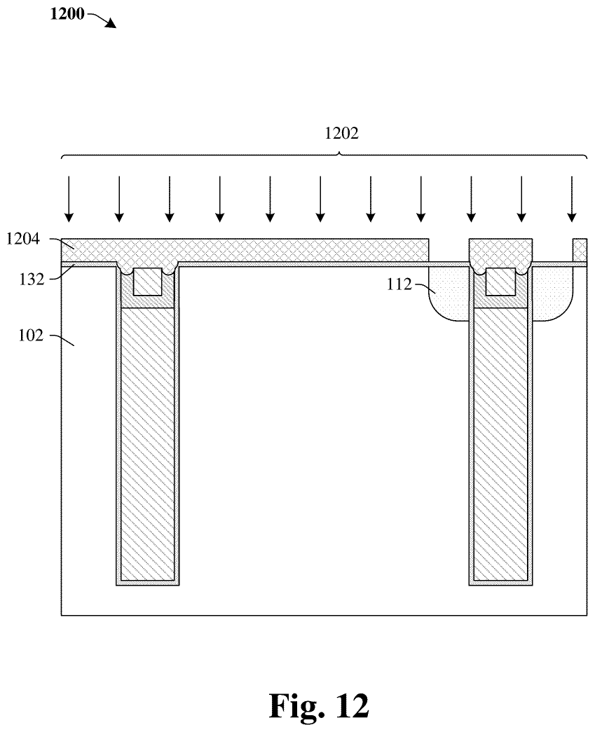

As shown in cross-sectional view 1200 of FIG. 12, a second masking layer 1204 is formed over the substrate 102. In some embodiments, the second masking layer 1204 is a photoresist. The second masking layer 1204 is subsequently patterned, forming openings in the second masking layer 1204 corresponding to the position of the floating node region 112 to be formed hereafter. After patterning the second masking layer 1204, a first implantation process 1202 is performed, doping the substrate 102 in a pattern corresponding to the openings in the second masking layer 1204 to form the floating node region 112. In some embodiments, the dopants are a first doping type (e.g., n-type doping). In some embodiments, dopants are implanted in the insulative layer 132 proximate to the floating node region 112. The second masking layer 1204 is subsequently removed.

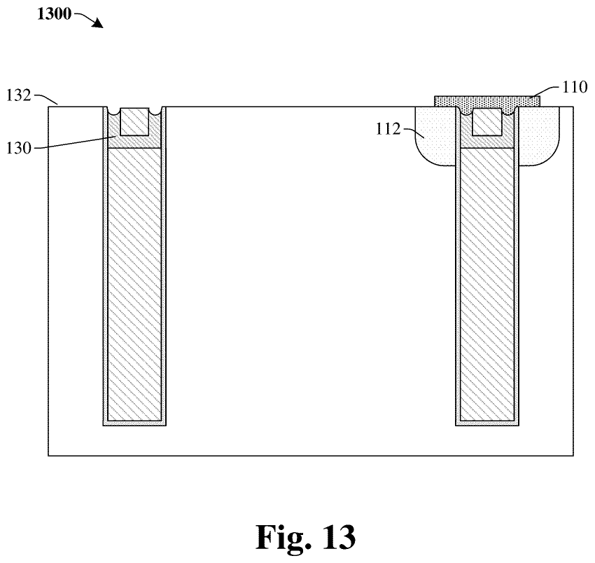

As shown in the cross-sectional view 1300 of FIG. 13, the floating node 110 is formed on the substrate 102 over the floating node region 112. In some embodiments, the floating node 110 is formed using one of CVD, PVD, ALD, epitaxy, some other suitable deposition process, or a combination of the foregoing. The floating node 110 is or comprises one of polysilicon, epitaxial silicon, a metal, another conductive material, or a combination of the above. The portion of the insulative layer 132 overlying the substrate 102 is removed prior to the formation of the floating node 110. In some embodiments, the portion of the insulative layer 132 overlying the substrate 102 is removed prior to the formation of the floating node 110 and the floating node region 112. Therefore, the floating node directly contacts the first side 102a of the substrate 102 and the floating node region 112.

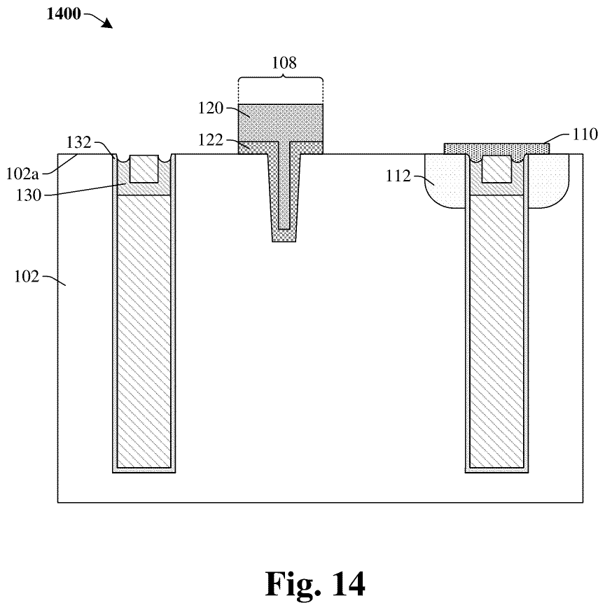

As shown in the cross-sectional view 1400 of FIG. 14, a transfer gate 108 is formed on the first side 102a of the substrate 102. Forming the transfer gate 108 comprises forming a gate dielectric 122 using one or more dry etching and deposition steps, and forming a conductive gate 120 over the gate dielectric using one or more dry etching and deposition steps. In some embodiments, the transfer gate 108 extends through the insulative layer 132 (if present) and into the substrate 102. In other embodiments, the transfer gate 108 overlies the first side 102a of the substrate 102 and does not extend into the substrate 102.

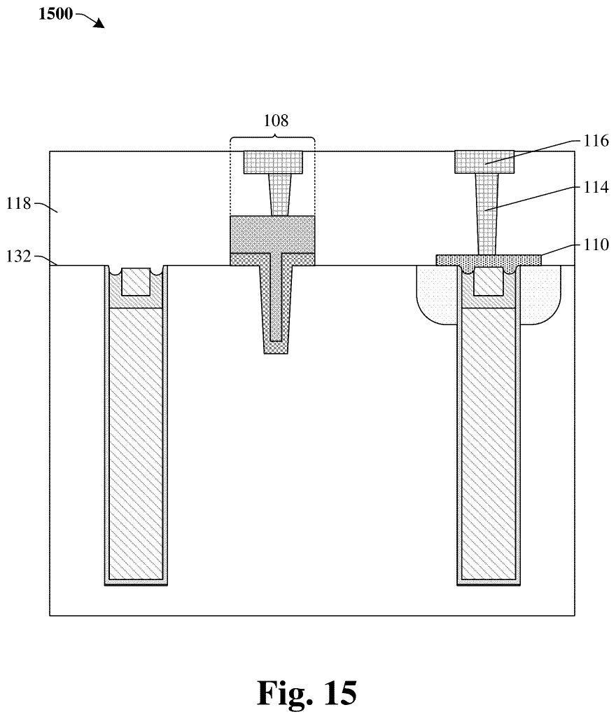

As shown in the cross-sectional view 1500 of FIG. 15, a dielectric 118 is formed over the insulative layer 132. Contacts 114 and an interconnect structure 116 are formed within the dielectric. The contacts 114 couple the floating node 110 and the transfer gate 108 to the interconnect structure 116. In some embodiments, the contacts 114 and the interconnect structure 116 are formed using one or more etching steps, one or more deposition steps, one or more damascene processes, one or more dual damascene processes, the like, or a combination of the foregoing.

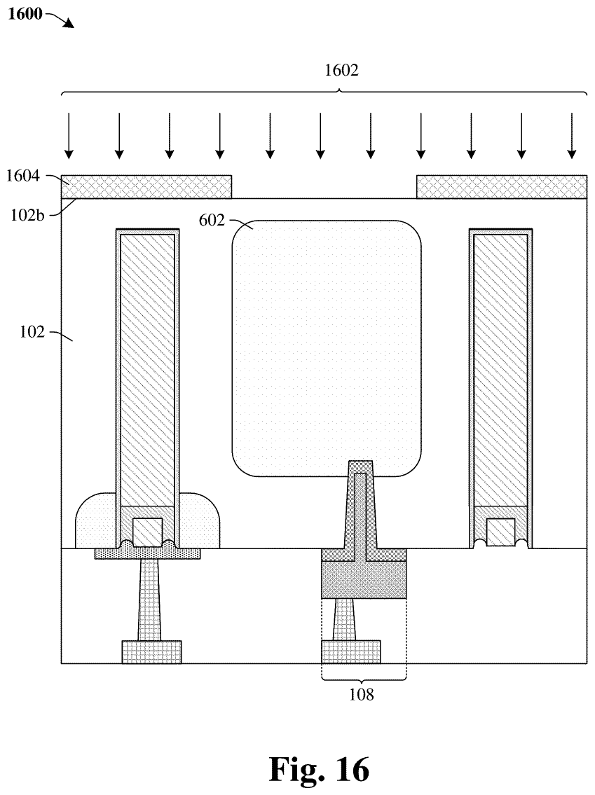

As shown in the cross-sectional view 1600 of FIG. 16, a third masking layer 1604 is formed over the second side 102b of the substrate 102. In some embodiments, the third masking layer 1604 is a photoresist. The third masking layer 1604 is then patterned. In some embodiments, the third masking layer 1604 is patterned using photolithography. A second implantation process 1602 is then performed. The second implantation process 1602 implants dopants according to the pattern of the third masking layer 1604, resulting in the photodetector 106 of the first doping type directly over the transfer gate 108. The third masking layer 1604, the is subsequently removed.

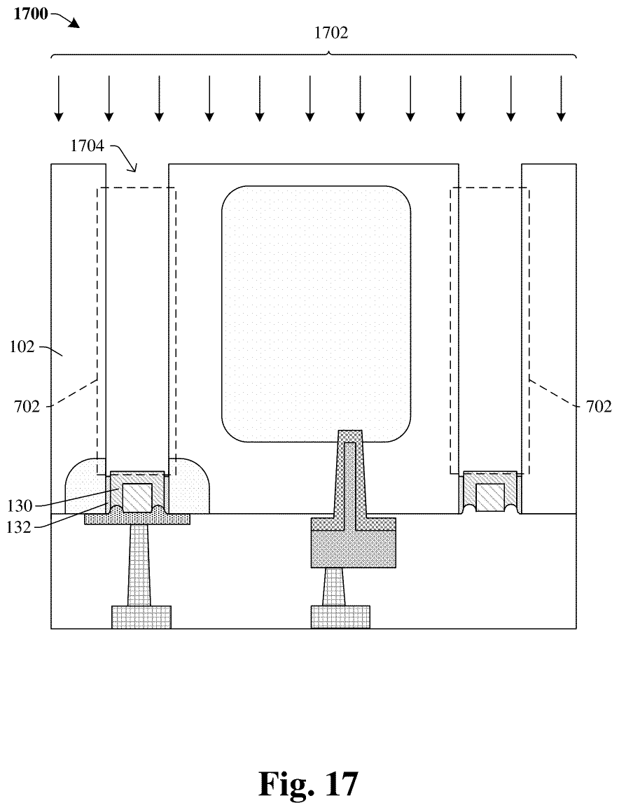

As shown in the cross-sectional view 1700 of FIG. 17, the first sacrificial core 702 (shown in phantom) is removed from the substrate 102, forming a second trench 1704. In some embodiments, the first sacrificial core 702 is removed using one or more etching processes 1702. In some embodiments, a portion of the substrate 102 is removed before the one or more etching processes 1702, exposing the first sacrificial core 702. In some embodiments, the one or more etching processes 1702 comprise a wet etching process with high selectivity. The wet etching process is a self-aligned etch. In some embodiments, the one or more etching processes 1702 may also remove portions of the insulative layer 132 previously surrounding the first sacrificial core 702. Further, portions of the insulative layer 132 surrounding outer sidewalls of the seal layer 130 may also be removed.

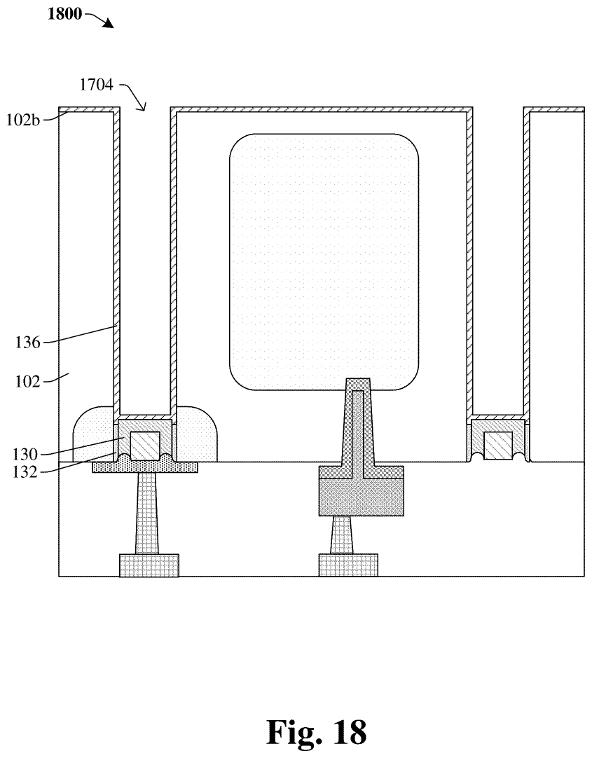

As shown in the cross-sectional view 1800 of FIG. 18, the high-k layer 136 is formed over the second side 102b of the substrate 102. In some embodiments, the high-k layer 136 is or comprises a high-k dielectric material, boron, a combination of the foregoing, or the like. The high-k layer 136 is configured to attract stray charge carriers from the substrate 102 and reduce the number of charge traps at the surface of the substrate 102, thereby reducing dark current in the image sensor being formed. The high-k layer 136 conforms to the second side 102b and the second trench 1704 within the substrate 102, resulting in the high-k layer 136 extending over the second side 102b and to the seal layer 130. In some embodiments, the high-k layer 136 extends up sidewalls of the seal layer 130 to contact the insulative layer 132, filling portions of the second trench 1704 that were occupied by the insulative layer 132 prior to the steps corresponding to FIG. 17.

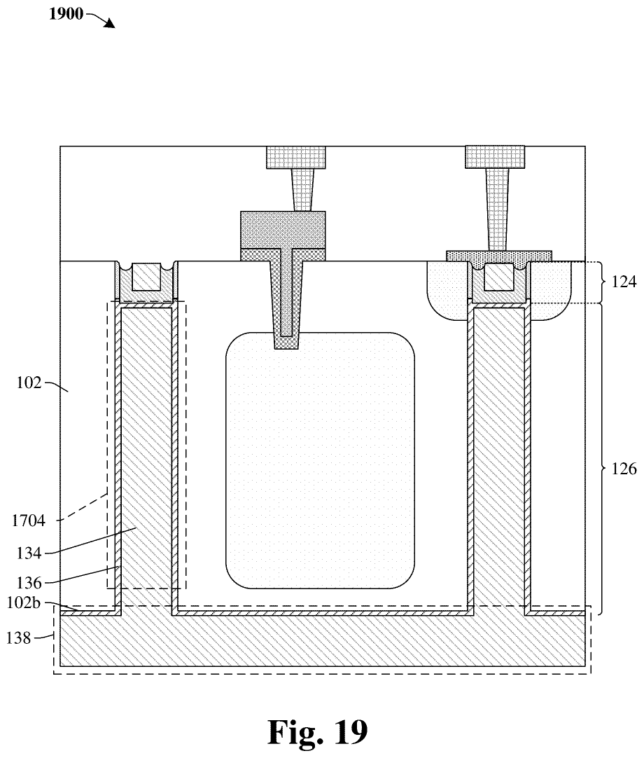

As shown in the cross-sectional view 1900 of FIG. 19, second insulative core 134 is formed within the second trench 1704, covering inner sidewalls of the high-k layer 136. The insulative base portion 138 is formed concurrently with the second insulative core, and covers portions of the high-k layer 136 on the second side 102b of the substrate 102. In some embodiments, the insulative base portion 138 and the second insulative core 134 both are or comprise an oxide (e.g., silicon dioxide (SiO₂)) or the like. In some embodiments, the second insulative core 134 is formed using one of CVD, PVD, ALD, some other suitable deposition process, or a combination of the foregoing. After the second insulative core 134 and the insulative base portion 138 are deposited, a planarization process may be performed to reduce the thickness of the insulative base portion 138. The insulative base portion 138 is configured to protect the high-k layer 136 from damage. The formation of the second insulative core 134 results in the completion of the backside DTI structure 126.

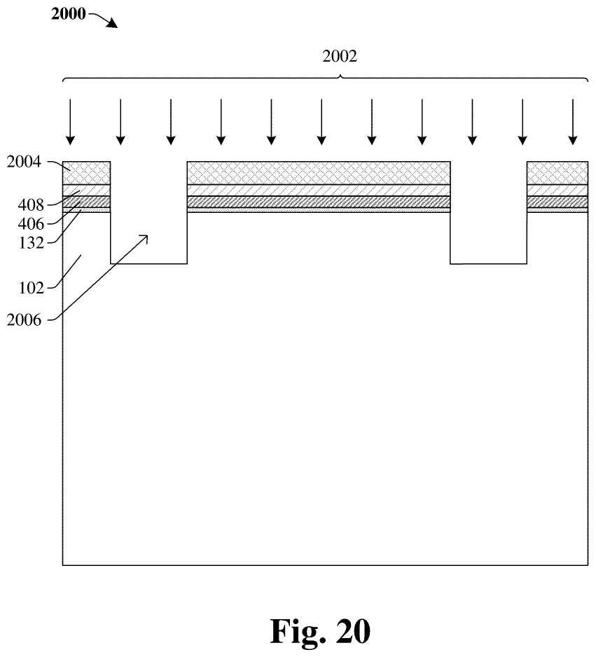

FIGS. 20-34 illustrate cross-sectional views of some embodiments of an alternative method of forming an image sensor having a DTI structure extending through the substrate with the backside DTI structure having with a lower width than the frontside DTI structure. Although FIGS. 20-34 are described in relation to a method, it will be appreciated that the structures disclosed in FIGS. 20-34 are not limited to such a method, but instead may stand alone as structures independent of the method. Although the numbered etching steps and other structures of FIGS. 20-34 follow the labelling conventions of FIGS. 4-19 (e.g., a third trench describe hereafter following the second trench of FIG. 16), it will be appreciated that the method related to FIGS. 20-34 is independent from the method related to FIGS. 4-19, and the method steps described hereafter are not limited to being subsequent to the method steps related to FIGS. 4-19.

As shown in cross-sectional view 2000 of FIG. 20, the substrate 102 is provided. The insulative layer 132 is formed on the substrate 102. In some embodiments, the insulative layer 132 is a thermal oxide. The first nitride layer 406 is formed over the insulative layer 132. The first hard mask layer 408 is formed over the first nitride layer 406. A fourth masking layer 2004 is formed over the first nitride layer 406. In some embodiments, the first nitride layer 406 and the first hard mask layer 408 are formed using one of CVD, PVD, ALD, some other suitable deposition process, or a combination of the foregoing. In some embodiments, the fourth masking layer 2004 is a photoresist. In some embodiments, the first nitride layer 406 is or comprises silicon nitride (Si₃N₄) or the like. In some embodiments, the first hard mask layer 408 is or comprises silicon oxide (SiO₂), densified silicon dioxide, or the like.

After the formation of the first masking layer 404, the fourth masking layer 2004 is then patterned to form openings. In some embodiments, the fourth masking layer 2004 is patterned using photolithography. A fourth etching process 2002 is then performed. During the fourth etching process 2002, the first hard mask layer 408, the first nitride layer 406, the insulative layer 132, and the substrate 102 are etched in the regions that are exposed by the fourth masking layer 2004. In some embodiments, fourth etching process 2002 may be a dry etch such as a plasma etch or the like. The fourth etching process 2002 results in a third trench 2006 formed in the substrate 102 in a pattern corresponding to the openings in the fourth masking layer 2004. The third trench 2006 has a depth that is less than the depth of the first trench 410 (see FIG. 4). The pattern is a grid pattern. The fourth masking layer 2004 is subsequently removed.

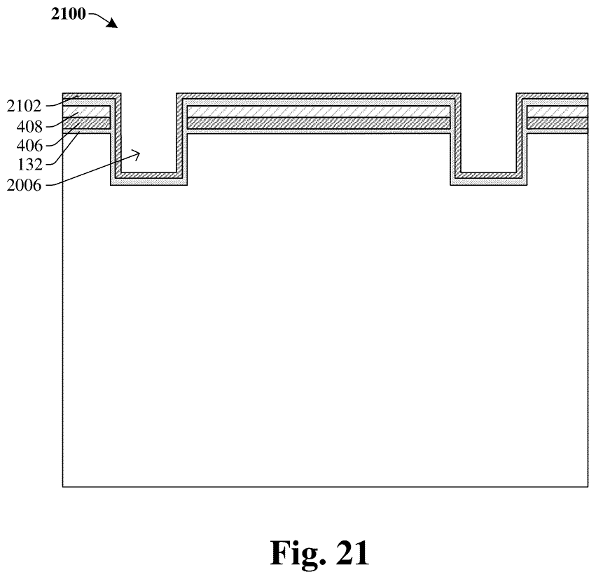

As shown in cross-sectional view 2100 of FIG. 21, a lining oxide is formed across the surface of the first trench 410, extending the insulative layer 132 along surfaces of the trench. After the lining oxide is formed, a conformal nitride layer 2102 is formed over the insulative layer 132. In some embodiments, the lining oxide is formed using a thermal process, a deposition process, or a combination of the foregoing. In some embodiments, the conformal nitride layer 2102 is formed using one of CVD, PVD, ALD, some other suitable deposition process, or a combination of the foregoing.

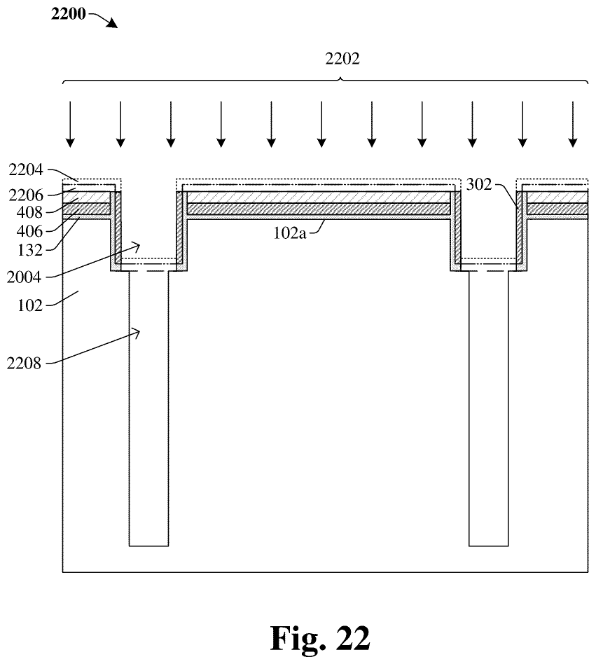

As shown in cross-sectional view 2200 of FIG. 22, a fifth etching process 2202 is performed, removing portions 2204 of the conformal nitride layer (see 2102 of FIG. 21) and portions 2206 of the insulative layer 132, resulting in a fourth trench 2208 extending further into the substrate 102. The fourth trench 2208 extends from a bottom surface of the third trench 2006, and has a lower width than the third trench 2006 due to portions of the conformal nitride layer 2102 and portions of the insulative layer 132 near the sidewalls of the third trench 2006 having a lower etch rate than the conformal nitride layer 2102 and the insulative layer 132 near the center of the third trench 2006. The first nitride layer 406 and the first hard mask layer 408 further prevent the fifth etching process 2202 from damaging the first side 102a of the substrate 102.

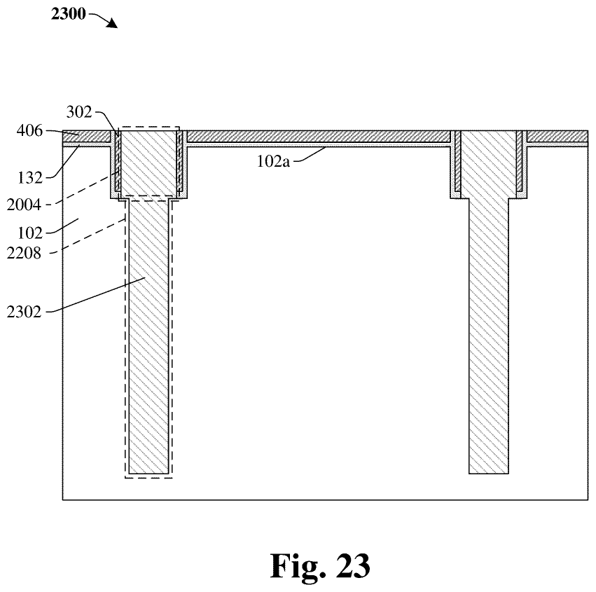

As shown in cross-sectional view 2300 of FIG. 23, a second sacrificial core 2302 is formed in the third trench 2006 (shown in phantom) and the fourth trench 2208 (shown in phantom). In some embodiments, the second sacrificial core 2302 is formed by depositing a conformal oxide layer (not shown) over the first side 102a of the substrate 102. The conformal oxide layer fills the third trench 2006 and the fourth trench 2208 and overlies the first hard mask layer 408. In some embodiments, the conformal oxide layer may be deposited using one of CVD, PVD, ALD, some other suitable deposition process, or a combination of the foregoing. After the conformal oxide layer is deposited, the first hard mask layer (see 408 of FIG. 22) and a portion of the conformal oxide layer extending over a top surface of the first nitride layer 406 are removed. In some embodiments, the portion of the conformal oxide layer and the first hard mask layer (see 408 of FIG. 22) are removed using a planarization process (e.g., a chemical mechanical planarization process). The removal process results in the second sacrificial core 2302 remaining in the substrate 102. The second sacrificial core 2302 lines inner sidewalls of the fourth trench 2208 (shown in phantom) and the second insulative layer 302.

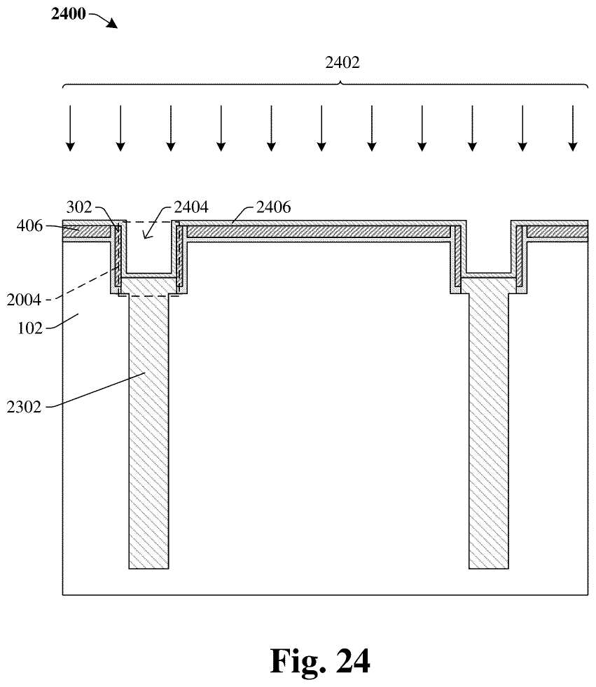

As shown in cross-sectional view 2400 of FIG. 24, a portion of the second sacrificial core 2302 is removed using a fifth etching process 2402, leaving a second opening 2404. In some embodiments, the fifth etching process 2402 is a wet etching process configured to selectively etch silicon dioxide (SiO₂).

After the second opening 2404 is formed, a second conformal seal layer 2406 is formed over the first nitride layer 406. In some embodiments, the second conformal seal layer 2406 is or comprises densified silicon dioxide (SiO₂), silicon nitride, polysilicon, a silicon epitaxial layer, a combination of the foregoing, or the like. The second conformal seal layer 2406 conforms to the second opening 2404 and the first nitride layer 406. In some embodiments, the second conformal seal layer 2406 may be deposited using one of CVD, PVD, ALD, some other suitable deposition process, or a combination of the foregoing.

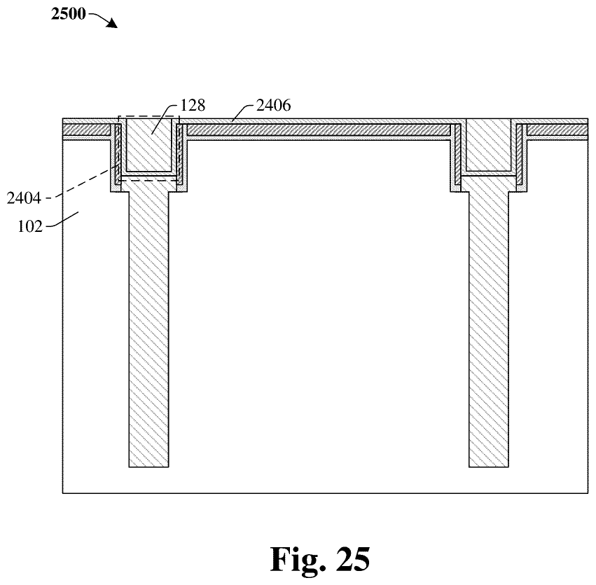

As shown in cross-sectional view 2500 of FIG. 25, a first insulative core 128 is formed over the second conformal seal layer 2406. The first insulative core 128 is formed by depositing a conformal oxide layer over the substrate 102, then removing portions of the conformal oxide layer over an upper surface of the second conformal seal layer 2406 using a planarization process (e.g., a CMP process). In some embodiments, the first insulative core is or comprises silicon dioxide (SiO₂) or the like.

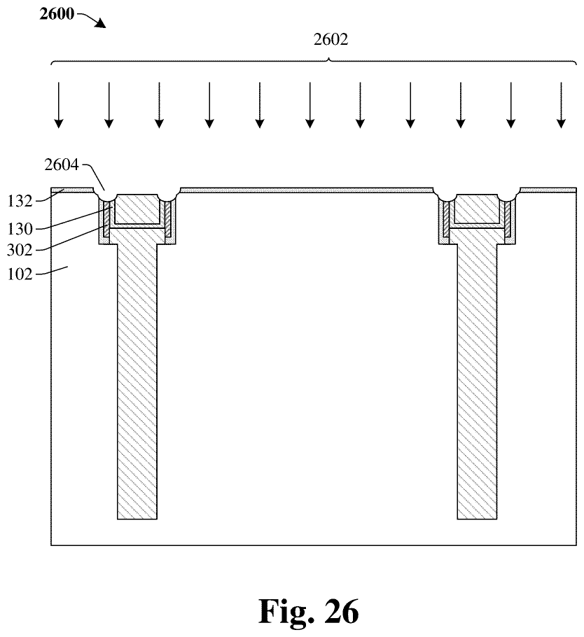

As shown in cross-sectional view 2600 of FIG. 26, portions of the second conformal seal layer (see 2406 of FIG. 25) over the first side 102a of the substrate 102, the first nitride layer (sec 406 of FIG. 24), and a portion of the second insulative layer 302 is removed, such that the seal layer 130 remains within the substrate 102. In some embodiments, the portions of the second conformal seal layer (see 2406 of FIG. 25), the first nitride layer (see 406 of FIG. 24), and the portions of the second insulative layer 302 are removed using one or more wet etching processes 2602. That is, in some embodiments, the portions of the second conformal seal layer (see 2406 of FIG. 25) may be removed using a first wet etching process selective for the material of the seal layer 130, and the first nitride layer (see 406 of FIG. 24) and portions of the second insulative layer 302 may subsequently be removed using a second wet etching process with an etch chemistry selective to silicon nitride. In some embodiments, where the seal layer 130 comprises a nitride (e.g., silicon nitride (Si₃N₄)), the portions of the second conformal seal layer (sec 2406 of FIG. 25), the first nitride layer (see 406 of FIG. 24), and the portions of the second insulative layer 302 may be removed using a single wet etching process 2602. The one or more wet etching processes 2602 result in indents 2604 being formed within the seal layer 130. In some embodiments, the one or more wet etching processes 2602 used to remove the portions of the second conformal seal layer (see 2406 of FIG. 25) and the first nitride layer (see 406 of FIG. 24) also remove portions of the insulative layer 132. In some embodiments, the one or more wet etching processes 2602 expose portions of the substrate 102 near the seal layer 130.

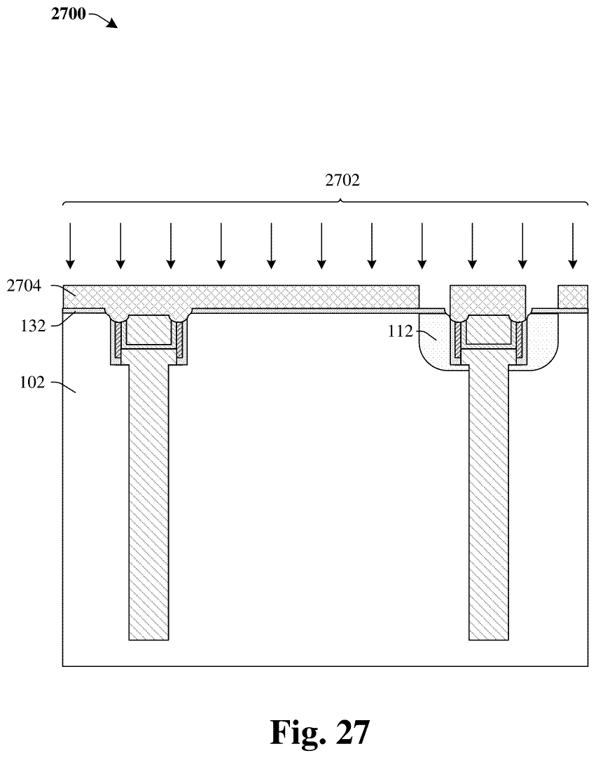

As shown in cross-sectional view 2700 of FIG. 27, a fifth masking layer 2704 is formed over the substrate 102. In some embodiments, the fifth masking layer 2704 is a photoresist. The fifth masking layer 2704 is subsequently patterned, forming openings in the fifth masking layer 2704 corresponding to the position of the floating node region 112 to be formed hereafter. After patterning the fifth masking layer 2704, a third implantation process 2702 is performed, doping the substrate 102 in a pattern corresponding to the openings in the fifth masking layer 2704 to form the floating node region 112. In some embodiments, the dopants are a first doping type (e.g., n-type doping). In some embodiments, dopants are implanted in the insulative layer 132 proximate to the floating node region 112. The fifth masking layer 2704 is subsequently removed.

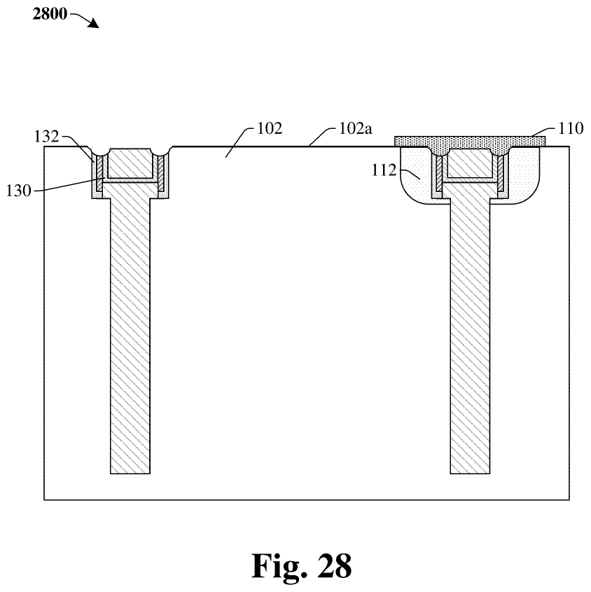

As shown in the cross-sectional view 2800 of FIG. 28, the floating node 110 is formed on the substrate 102 over the floating node region 112. In some embodiments, the floating node 110 is formed using one of CVD, PVD, ALD, epitaxy, some other suitable deposition process, or a combination of the foregoing. The floating node 110 is or comprises one of polysilicon, epitaxial silicon, a metal, another conductive material, or a combination of the above. In some embodiments, the floating node region 112 is exposed by previous etching processes, resulting in the floating node 110 directly contacting the floating node region. In other embodiments, a portion of the insulative layer 132 extends between the floating node 110 and the floating node region 112. The thickness of the portion of the insulative layer 132 between the floating node 110 and the floating node region 112 is very small, such that the charge from the photodetector (see 106 of FIG. 1) may conduct from the floating node region 112 to the floating node 110 during operation of the image sensor via quantum tunneling or the like. In yet other embodiments, an etching process is preformed to remove portions of the insulative layer 132 prior to the formation of the floating node 110, resulting in lower surfaces of the floating node 110 directly contacting the first side 102a of the substrate and the floating node region 112.

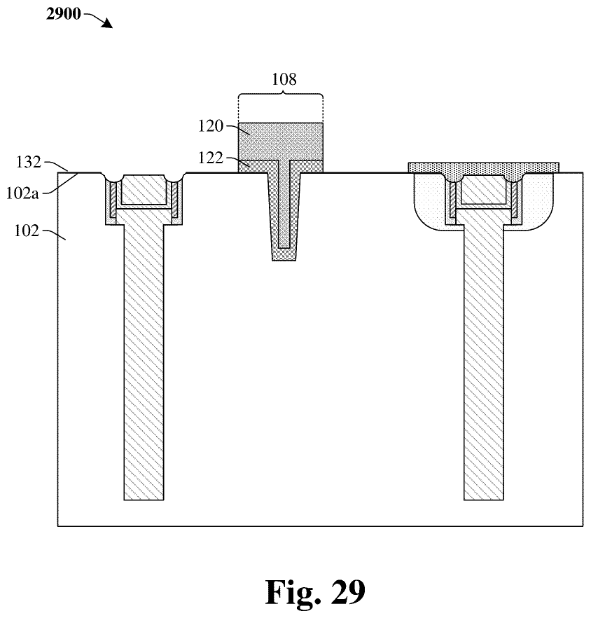

As shown in the cross-sectional view 2900 of FIG. 29, a transfer gate 108 is formed on the first side 102a of the substrate 102. Forming the transfer gate 108 comprises forming a gate dielectric 122 using one or more dry etching and deposition steps, and forming a conductive gate 120 over the gate dielectric using one or more dry etching and deposition steps. In some embodiments, the transfer gate 108 extends through the first side 102a and the insulative layer 132 (if present) and into the substrate 102. In other embodiments, the transfer gate 108 overlies the first side 102a of the substrate 102 and does not extend into the substrate 102.

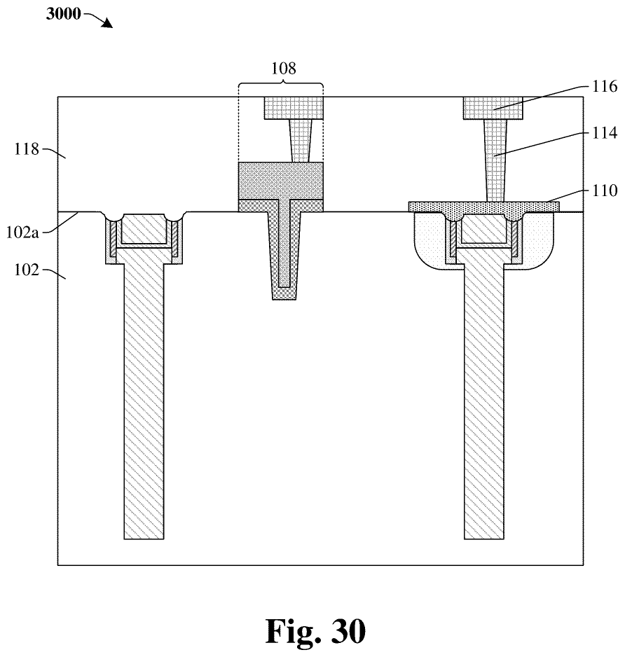

As shown in the cross-sectional view 3000 of FIG. 30, a dielectric 118 is formed over the first side 102a of the substrate 102. Contacts 114 and an interconnect structure 116 are formed within the dielectric. The contacts 114 couple the floating node 110 and the transfer gate 108 to the interconnect structure 116. In some embodiments, the contacts 114 and the interconnect structure 116 are formed using one or more etching steps, one or more deposition steps, one or more damascene processes, the like, or a combination of the foregoing.

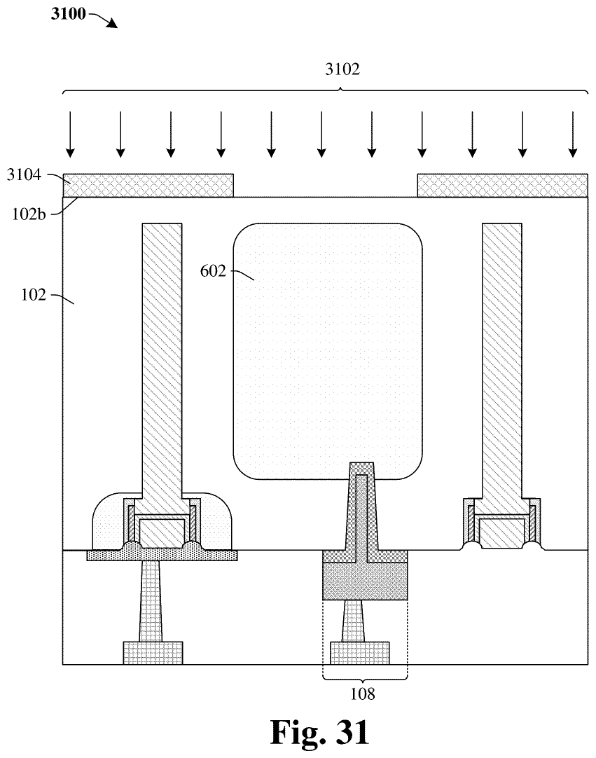

As shown in the cross-sectional view 3100 of FIG. 31, a sixth masking layer 3104 is formed over the second side 102b of the substrate 102. In some embodiments, the sixth masking layer 3104 is a photoresist. The sixth masking layer 3104 is then patterned. In some embodiments, the sixth masking layer 3104 is patterned using photolithography. A fourth implantation process 3102 is then performed. The fourth implantation process 3102 implants dopants according to the pattern of the sixth masking layer 3104, resulting in the photodetector 106 of the first doping type directly over the transfer gate 108. The sixth masking layer 3104, the is subsequently removed.

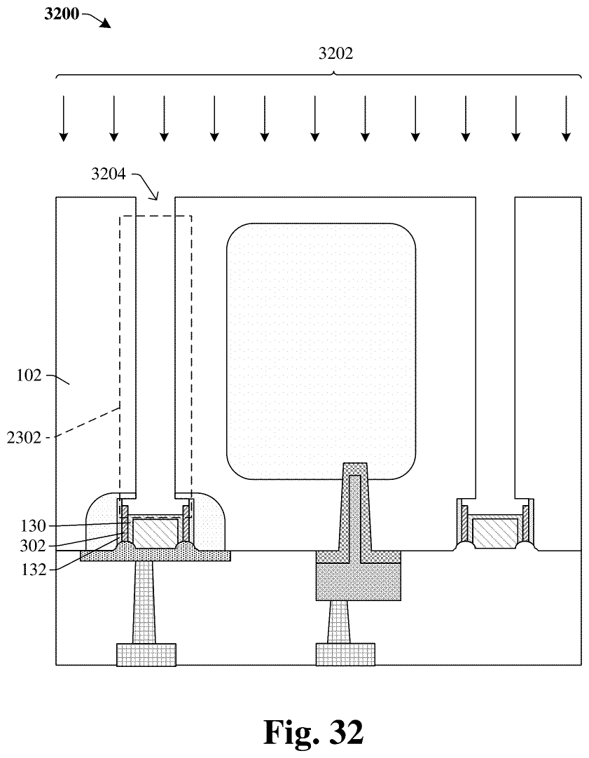

As shown in the cross-sectional view 3200 of FIG. 32, the second sacrificial core 2302 (shown in phantom) is removed from the substrate 102, forming a fifth trench 3204. In some embodiments, the second sacrificial core 2302 is removed using one or more etching processes 3202. In some embodiments, a portion of the substrate 102 is removed before the one or more etching process 3202, exposing the second sacrificial core 2302. In some embodiments, the one or more etching processes 3202 comprise a wet etching process. The wet etching process is a self-aligned etch. In some embodiments, the one or more etching processes 3202 may also remove portions of the insulative layer 132 previously surrounding the second sacrificial core 2302. Further, portions of the insulative layer 132 surrounding outer sidewalls of the seal layer 130 may also be removed.

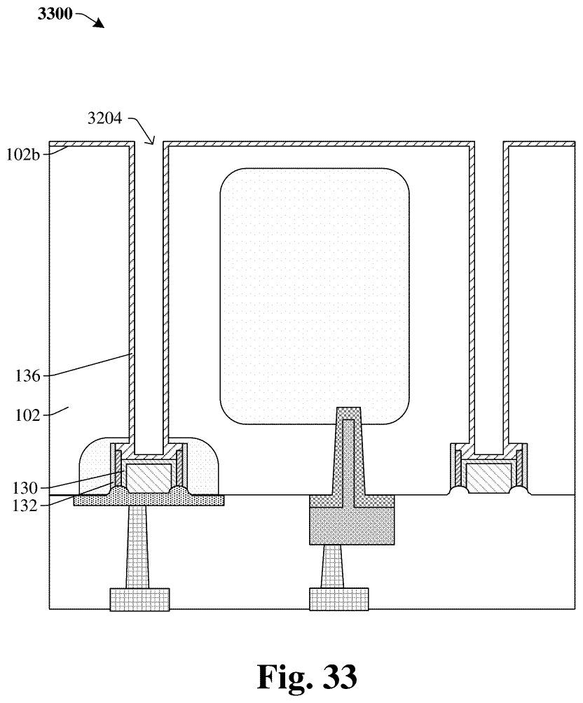

As shown in the cross-sectional view 3300 of FIG. 33, the high-k layer 136 is formed over the second side 102b of the substrate 102. In some embodiments, the high-k layer 136 is or comprises a high-k dielectric material, boron, a combination of the foregoing, or the like. The high-k layer 136 is configured to attract stray charge carriers from the substrate 102 and reduce the number of charge traps at the surface of the substrate 102, thereby reducing dark current in the image sensor being formed. The high-k layer 136 conforms to the second side 102b and the fifth trench 3204 within the substrate 102, resulting in the high-k layer 136 extending over the second side 102b and to the seal layer 130. In some embodiments, the high-k layer 136 extends across surfaces of the seal layer 130 to contact the insulative layer 132, filling portions of the second trench 1704 that were occupied by the insulative layer 132 prior to the steps corresponding to FIG. 32.

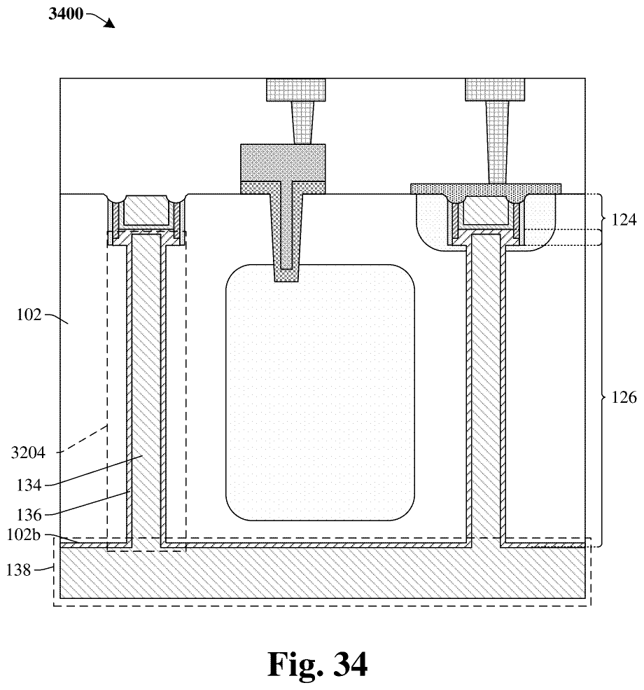

As shown in the cross-sectional view 3400 of FIG. 34, second insulative core 134 is formed within the fifth trench 3204, covering inner sidewalls of the high-k layer 136. The insulative base portion 138 is formed concurrently with the second insulative core, and covers portions of the high-k layer 136 on the second side 102b of the substrate 102. In some embodiments, the second insulative core 134 is formed using one of CVD, PVD, ALD, some other suitable deposition process, or a combination of the foregoing. After the second insulative core 134 and the insulative base portion 138 are deposited, a planarization process may be performed to reduce the thickness of the insulative base portion 138. The insulative base portion 138 is configured to protect the high-k layer 136 from damage. The formation of the second insulative core 134 results in the completion of the backside DTI structure 126 beneath the frontside DTI structure 124.

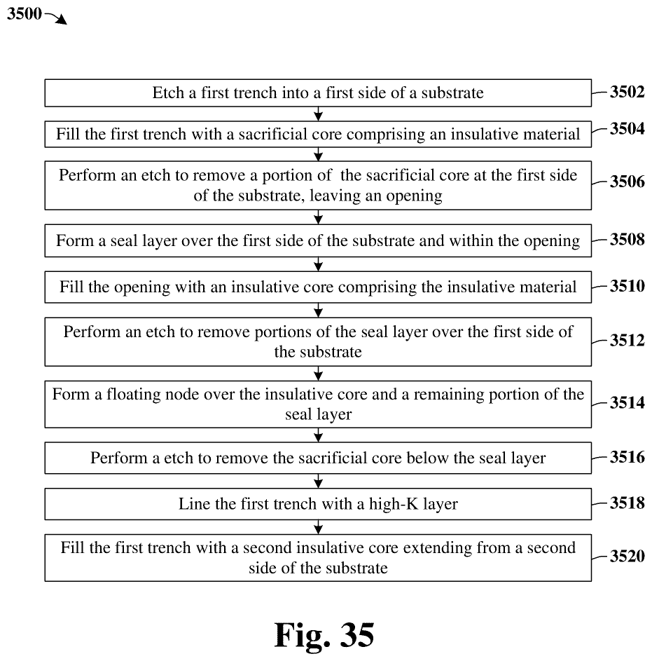

FIG. 35 illustrates a flow diagram of some embodiments of a method of forming an integrated chip having an image sensor having a DTI structure extending through the substrate.

While method 3500 is illustrated and described below as a series of acts or events, it will be appreciated that the illustrated ordering of such acts or events are not to be interpreted in a limiting sense. For example, some acts may occur in different orders and/or concurrently with other acts or events apart from those illustrated and/or described herein. In addition, not all illustrated acts may be required to implement one or more aspects or embodiments of the description herein. Further, one or more of the acts depicted herein may be carried out in one or more separate acts and/or phases.

At 3502, a first trench is etched into a first side of a substrate. FIG. 4 illustrates a cross-sectional view 400 of some embodiments corresponding to act 3502.

At 3504, the first trench is filled with a sacrificial core comprising an insulative material. FIGS. 6-7 illustrate cross-sectional views 600-700 of some embodiments corresponding to act 3504.

At 3506, an etch is performed to remove a portion of the sacrificial core at the first side of the substrate, leaving an opening. FIG. 8 illustrates a cross-sectional view 800 of some embodiments corresponding to act 3506.

At 3508, a seal layer is formed over the first side of the substrate and within the opening. FIG. 10 illustrates a cross-sectional view 1000 of some embodiments corresponding to act 3508.

At 3510, the opening is filled with an insulative core comprising the insulative material. FIG. 10 illustrates a cross-sectional view 1000 of some embodiments corresponding to act 3510.

At 3512, an etch is performed to remove portions of the seal layer over the first side of the substrate. FIG. 11 illustrates a cross-sectional view 1100 of some embodiments corresponding to act 3512.

At 3514, a floating node is formed over the insulative core and a remaining portion of the seal layer. FIG. 13 illustrates a cross-sectional view 1300 of some embodiments corresponding to act 3514.

At 3516, an etch is performed to remove the sacrificial core below the seal layer. FIG. 17 illustrates a cross-sectional view 1700 of some embodiments corresponding to act 3516.

At 3518, the first trench is lined with a high-k layer. FIG. 18 illustrates a cross-sectional view 1800 of some embodiments corresponding to act 3518.

At 3520, the first trench is filled with a second insulative core extending from a second side of the substrate. FIG. 19 illustrates a cross-sectional view 1900 of some embodiments corresponding to act 3520.

Therefore, the present disclosure relates to a new method of forming an integrated chip having an image sensor having a DTI structure extending through the substrate.

Accordingly, in some embodiments, the present disclosure relates to an image sensor including a substrate having a first side and a second side opposite the first side; a photodetector within the substrate; a gate structure on the first side of the substrate over the photodetector; a deep trench isolation (DTI) structure surrounding the photodetector and extending from the first side of the substrate to the second side; a doped floating node region within the substrate at the first side and disposed between the gate structure and the DTI structure; and a floating node on the first side of the substrate, contacting a top surface of the DTI structure and overlying the doped floating node region.

In other embodiments, the present disclosure relates to an image sensor including a substrate having a first side and a second side opposite the first side; a plurality of photodetectors within the substrate; a plurality of gate structures overlying the plurality of photodetectors on the first side of the substrate; a deep-trench isolation (DTI) structure comprising segments surrounding the plurality of photodetectors in a grid pattern, isolating the plurality of photodetectors from one another, where a plurality of the segments intersect at a crossing; a floating node extending over the crossing within the grid pattern of the DTI structure between the plurality of gate structures, the floating node extending past outer sidewalls of the segments intersecting at the crossing and towards the plurality of photodetectors.

In yet other embodiments, the present disclosure relates to a method of forming an image sensor, including etching a first trench into a first side of a substrate; filling the first trench with a sacrificial core comprising an insulative material; performing a etch to remove a portion of the sacrificial core at the first side of the substrate, leaving an opening; forming a seal layer over the first side of the substrate and within the opening; filling the opening with an insulative core comprising the insulative material; performing a etch to remove portions of the seal layer over the first side of the substrate; forming a floating node over the insulative core and a remaining portion of the seal layer; performing a etch to remove the sacrificial core below the seal layer; lining the first trench with a high-k layer; filling the first trench with a second insulative core extending from a second side of the substrate.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. An image sensor, comprising:
a substrate, having a first side and a second side opposite the first side;
a photodetector within the substrate;
a gate structure on the first side of the substrate over the photodetector;
a deep trench isolation (DTI) structure surrounding the photodetector and extending from the first side of the substrate to the second side;
a doped floating node region within the substrate at the first side and disposed between the gate structure and the DTI structure; and
a floating node on the first side of the substrate, contacting a top surface of the DTI structure and overlying the doped floating node region.

2. The image sensor of claim 1, wherein the DTI structure further comprises:
a frontside DTI structure extending from the first side to a first depth within the substrate, the frontside DTI structure comprising a first insulative core surrounded by a seal layer and an oxide lining; and
a backside DTI structure extending from the second side to the first depth within the substrate, the backside DTI structure comprising a second insulative core surrounded by a high-k layer.

3. The image sensor of claim 2, wherein the frontside DTI structure has a first width measured from a first sidewall of the oxide lining to a second sidewall of the oxide lining, and the high-k layer has a second width measured from a first sidewall of the high-k layer to a second sidewall of the high-k layer, and wherein the second width is equal to or less than the first width.

4. The image sensor of claim 2, wherein a top surface of the backside DTI structure extends to a first height measured from the second side of the substrate, and a bottom surface of the frontside DTI structure extends to a second height measured from the second side of the substrate that is greater than the first height.

5. The image sensor of claim 2, wherein the high-k layer has protrusions extending from outer surfaces of the high-k layer towards the oxide lining and contacting the oxide lining.

6. The image sensor of claim 2, wherein the backside DTI structure has both a first width measured at an elevation beneath the frontside DTI structure and a second width measured at an elevation above the first depth, wherein the second width is greater than the first width.

7. The image sensor of claim 1, wherein the floating node further comprises:
protrusions extending into the DTI structure; and
a lower surface extending between the protrusions, wherein the protrusions extend further into the DTI structure than the lower surface.

8. An image sensor, comprising:
a substrate having a first side and a second side opposite the first side;
a plurality of photodetectors within the substrate;
a plurality of gate structures on the first side of the substrate overlying the plurality of photodetectors;
a deep-trench isolation (DTI) structure comprising segments surrounding the plurality of photodetectors in a grid pattern, isolating the plurality of photodetectors from one another, wherein a plurality of the segments intersect at a crossing; and
a floating node extending over the crossing within the grid pattern of the DTI structure and between the plurality of gate structures, wherein the floating node extends past outer sidewalls of the segments at the crossing.

9. The image sensor of claim 8, wherein a top surface of the DTI structure has indentations surrounding a flat upper surface, and wherein the floating node has protrusions that fill the indentations at the crossing within the grid pattern.

10. The image sensor of claim 9, wherein the indentations extend in a square pattern around openings in the grid pattern.

11. The image sensor of claim 8, wherein the DTI structure further comprises:
a frontside DTI structure on the first side of the substrate and comprising an insulative core surrounded by a seal layer, the seal layer having a “U” shaped cross-section; and
a backside DTI structure on the second side of the substrate and extending to a bottom surface of the seal layer.

12. The image sensor of claim 11, further comprising an insulative base portion on the second side of the substrate, wherein the backside DTI structure extends from the insulative base portion, and wherein the backside DTI structure further comprises a second insulative core and a high-k layer separating the second insulative core from the substrate.

13. The image sensor of claim 12, wherein the high-k layer extends over the second side of the substrate, separating the insulative base portion from the substrate.

14. The image sensor of claim 8, wherein the floating node is surrounded by a floating node region of a first doping type and extends into the substrate surrounding the crossing within the grid pattern.

15. A method of forming an image sensor, comprising:
performing a first etch to form a first trench into a first side of a substrate;
filling the first trench with a sacrificial core comprising an insulative material;
performing a second etch to remove a portion of the sacrificial core at the first side of the substrate, leaving an opening;
forming a seal layer over the first side of the substrate and within the opening;
filling the opening with an insulative core comprising the insulative material;
performing a third etch to remove portions of the seal layer over the first side of the substrate;
forming a floating node over the insulative core and a remaining portion of the seal layer;
performing a fourth etch to remove the sacrificial core below the seal layer, forming a second trench;
lining the second trench with a high-k layer; and
filling the second trench with a second insulative core extending from a second side of the substrate.

16. The method of claim 15, further comprising:
forming a photodetector adjacent to the sacrificial core between the removal of the portions of the seal layer and the removal of the sacrificial core; and
forming a floating node region before the removal of the sacrificial core.

17. The method of claim 15, further comprising forming an insulative layer in the first trench before forming the seal layer, wherein the removal of the sacrificial core below the seal layer further removes a portion of the insulative layer surrounding the seal layer, and wherein lining the second trench with the high-k layer results in the high-k layer replacing the portion removed from the insulative layer.

18. The method of claim 15, further comprising:
etching an initial trench before etching the first trench into the first side of the substrate; and
lining the initial trench with a first insulative layer comprising a first material and a second insulative layer comprising a second material different from the first material, wherein the etching of the first trench is a self-aligned etch using the first insulative layer and the second insulative layer to delineate sidewalls of the first trench.

19. The method of claim 15, further comprising forming a plurality of photodetectors in the substrate between the removal of portions of the seal layer and the removal of the sacrificial core, wherein the first trench is etched in a grid pattern, and wherein the plurality of photodetectors are formed between segments of the grid pattern.

20. The method of claim 15, further comprising forming an insulative base concurrent with the formation of the second insulative core, wherein the insulative base covers the second side of the substrate.
